(19) United States
(12) Patent Application Publication
(10) Pub. No.: US 2024/0250063 A1
(43) Pub. Date: Jul. 25, 2024

(54) METHODS OF AUTOMATIC RECOVERY FOR PROCESS ERRORS IN OPERATING WIRE BONDING MACHINES

(71) Applicant: Kulicke and Soffa Industries, Inc., Fort Washington, PA (US)

(72) Inventors: Hui Xu, Chalfont, PA (US); Gary S. Gillotti, North Wales, PA (US)

(73) Assignee: Kulicke and Soffa Industries, Inc., Fort Washington, PA (US)

(21) Appl. No.: 18/412,719

(22) Filed: Jan. 15, 2024

Related U.S. Application Data
(60) Provisional application No. 63/440,300, filed on Jan. 20, 2023.

(51) Int. Cl. H01L 23/00

(52) U.S. Cl. CPC H01L 24/85; H01L 24/43; H01L 24/78; H01L 2224/432; H01L 2224/437; H01L 2224/78824; H01L 2224/859

(57) ABSTRACT

A method of operating a wire bonding machine is provided. The method includes the steps of: (a) attempting to bond a free air ball to a first bonding location using a wire bonding tool; (b) detecting that the free air ball was not properly bonded to the first bonding location in step (a); (c) bonding the free air ball to a second bonding location; (d) raising the wire bonding tool, with a wire engaged with the wire bonding tool continuous with the bonded free air ball, to a position above the bonded free air ball; (e) weakening a neck portion of a wire above the free air ball after step (d); and (f) separating the bonded free air ball from the wire after step (e) such that a wire tail extends below a tip of a wire bonding tool.

### CROSS-REFERENCE TO RELATED APPLICATION

This application claims the benefit of U.S. Provisional Application No. 63/440,300, filed Jan. 20, 2023, the content of which is incorporated herein by reference.

### FIELD

The invention relates to wire bonding operations, and in particular, to techniques for operating wire bonding machines under various process error conditions.

### BACKGROUND

In the processing and packaging of semiconductor devices, wire bonding continues to be a primary method of providing electrical interconnection between two locations within a package (e.g., between a die pad of a semiconductor die and a lead of a leadframe). More specifically, using a wire bonder (also known as a wire bonding machine) wire loops are formed between respective locations to be electrically interconnected. The primary methods of forming wire loops are ball bonding and wedge bonding. In forming the bonds between (a) the ends of the wire loop and (b) respective bonding locations (e.g., a die pad, a lead, etc.), varying types of bonding energy may be used, for example, ultrasonic energy, thermosonic energy, thermocompressive energy, amongst others. Wire bonding machines (e.g., stud bumping machines) are also used to form conductive bumps from portions of wire.

During ball bonding operations, a tail of wire extending from the tip of a bonding tool (e.g., a capillary) is melted into a free air ball using a spark from an electronic flame-off (EFO) device. The free air ball is then used to form a first bond (e.g., a ball bond) of a wire loop at a first bonding location, and then wire is extended from the ball bond to a second bonding location, where a second bond (e.g., a stitch bond) of the wire loop is formed by bonding a portion of the wire to the second bonding location using the bonding tool. For example, the first bonding location may be a bonding pad of a semiconductor die, and the second bonding location may be a lead of a leadframe.

In connection with such wire bonding operations, a number of challenging situations may occur. For example, during bonding of a first bond of a wire loop, the free air ball may not be properly bonded to a bonding location. This situation is sometimes referred to as a NSOP condition (a no stick on pad condition). In another example, a second bond of a wire loop may not be properly bonded to a bonding location. This situation is sometimes referred to as a NSOL condition (a no stick on lead condition). Exemplary processes for addressing such “no stick” conditions are disclosed in U.S. Pat. No. 8,899,469 entitled “AUTOMATIC REWORK PROCESSES FOR NON-STICK CONDITIONS IN WIRE BONDING OPERATIONS”.

Another challenge in wire bonding operations relates to a so called “short tail condition”. For example, after formation of a stitch bond at a second bond location of a wire loop, a bonding tool may be raised to a short tail detect height where the wire is tested (e.g., an electrical continuity test) to ensure it is still continuous with the stitch bond on the second bonding location. If a short tall is not detected, the bond head (i.e., carrying the bonding tool and a wire clamp, now closed) is raised to tear the wire at the stitch bond. The remaining wire tail length may then be used to form another free air ball for another wire loop. However, a short tail may be detected. Short tail conditions may result in a number of problems during wire bonding such as, for example, inconsistent free air ball size and shape. Exemplary techniques for addressing such “short tail” conditions are disclosed in U.S. Pat. No. 9,165,842 entitled “SHORT TAIL RECOVERY TECHNIQUES IN WIRE BONDING OPERATIONS”.

The content of each of U.S. Pat. Nos. 8,899,469 and 9,165,842 is incorporated by reference herein in their entirety.

Thus, it would be desirable to provide improved methods for automatic recovery of the above described challenges in operating wire bonding machines.

### SUMMARY

According to an exemplary embodiment of the invention, a method of operating a wire bonding machine is provided. The method includes the steps of: (a) attempting to bond a free air ball to a first bonding location using a wire bonding tool; (b) detecting that the free air ball was not properly bonded to the first bonding location in step (a); (c) bonding the free air ball to a second bonding location; (d) raising the wire bonding tool, with a wire engaged with the wire bonding tool continuous with the bonded free air ball, to a position above the bonded free air ball (e.g., to a tail height position); (e) weakening a neck portion of a wire above the free air ball after step (d); and (f) separating the bonded free air ball from the wire after step (e) such that a wire tail extends below a tip of a wire bonding tool.

According to another exemplary embodiment of the invention, another method of operating a wire bonding machine is provided. The method includes the steps of: (a) forming a first bond of a wire loop at a first bonding location using a wire bonding tool; (b) extending a length of wire, continuous with the first bond, to a second bonding location; (c) attempting to bond a portion of the length of wire to the second bonding location using the wire bonding tool; (d) detecting that the portion of the length of wire was not properly bonded to the second bonding location in step (c); (e) separating the portion of the length of wire from the first bond; (f) bending the portion of the length of wire against a bending location; and (g) bonding the portion of the length of wire to a third bonding location.

According to yet another exemplary embodiment of the invention, yet another method of operating a wire bonding machine is provided. The method includes the steps of: detecting a short tail condition after formation of a wire loop, wherein a short wire tail extends from a tip of a wire bonding tool; forming a free air ball using the short wire tail; extending a length of wire below a tip of the wire bonding tool, continuous with the free air ball, to create a first wire tail; and bonding the first wire tail to a first bonding location.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1G are a series of block diagrams of portions of a wire bonding machine useful for illustrating a method of operating a wire bonding machine in an NSOP condition in accordance with various exemplary embodiments of the invention;

FIGS. 2A-2L are a series of block diagrams of portions of a wire bonding machine useful for illustrating another method of operating a wire bonding machine in an NSOP condition in accordance with various exemplary embodiments of the invention;

FIGS. 3A-3M are a series of block diagrams of portions of a wire bonding machine useful for illustrating yet another method of operating a wire bonding machine in an NSOP condition in accordance with various exemplary embodiments of the invention;

FIGS. 4A-4K are a series of block diagrams of portions of a wire bonding machine useful for illustrating a method of operating a wire bonding machine in an NSOL condition in accordance with various exemplary embodiments of the invention;

FIGS. 5A-5L are a series of block diagrams of portions of a wire bonding machine useful for illustrating another method of operating a wire bonding machine in an NSOL condition in accordance with various exemplary embodiments of the invention;

FIGS. 6A-6K are a series of block diagrams of portions of a wire bonding machine useful for illustrating a method of operating a wire bonding machine in a short wire tail condition in accordance with various exemplary embodiments of the invention;

FIGS. 7A-7L are a series of block diagrams of portions of a wire bonding machine useful for illustrating a method of operating a wire bonding machine in another short wire tail condition in accordance with various exemplary embodiments of the invention; and

FIGS. 8-10 are flow diagrams of various methods of operating a wire bonding machine in accordance with various exemplary embodiments of the invention.

### DETAILED DESCRIPTION

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.). In connection with the invention, a semiconductor element is an example of a workpiece. Another example of a workpiece is a semiconductor element mounted on a substrate (e.g., a semiconductor die mounted on a leadframe). Yet another example of a workpiece is a plurality of semiconductor elements.

Aspects of the invention relate to wire bonding machine features that provide recovery processes (e.g., automatic recovery processes, without requiring operator intervention) for various error conditions such as NSOP conditions, NSOL conditions, short tail conditions, long tail conditions, amongst others.

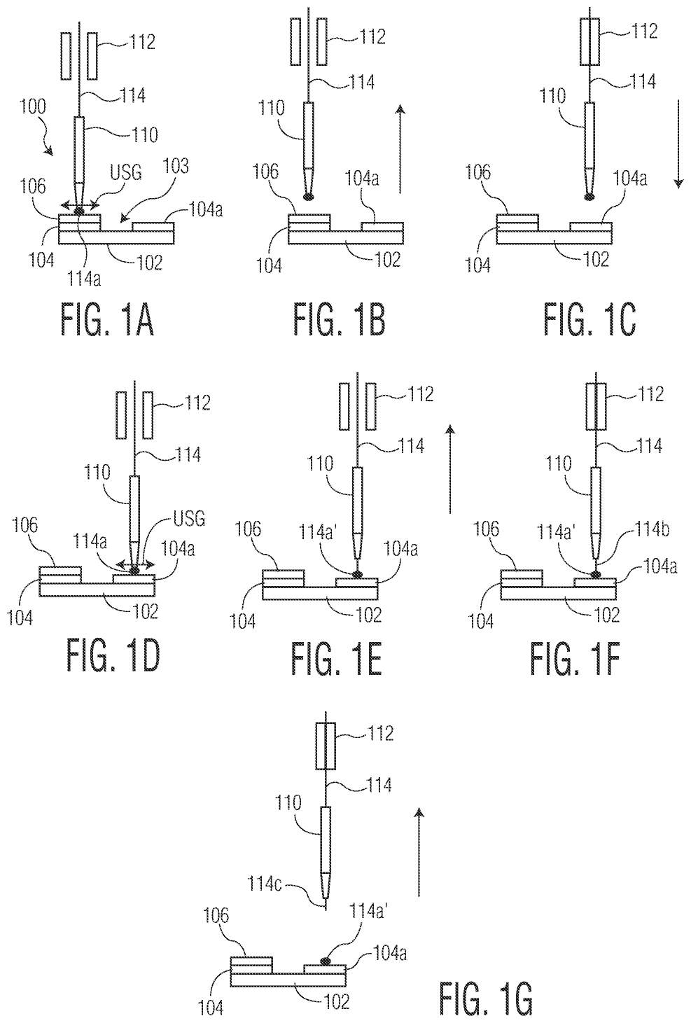

Exemplary aspects of the invention relate to NSOP auto recovery processes whereby a lifted free air ball (e.g., a free air ball that was not properly bonded to a desired bonding location in a first bonding process, such as the design first bonding location) is bonded in connection with a second bonding process to another bonding location (e.g., the design second bonding location, or another bonding location). For example, see the processes illustrated in FIGS. 1A-1G, FIGS. 2A-2L, and FIGS. 3A-3M. This second bonding process may utilize the same bonding parameters (e.g., bonding force, ultrasonic energy, bonding time, etc.) as used in the attempted first bonding process, or different bonding parameters. Such techniques may also include a “neck” weakening method to weaken the wire in the neck area before breaking the wire, to have a desirable tail length (e.g., a tail length within a predetermined specification). Advanced auto bond off processes may also be conducted to ensure the tail length and quality.

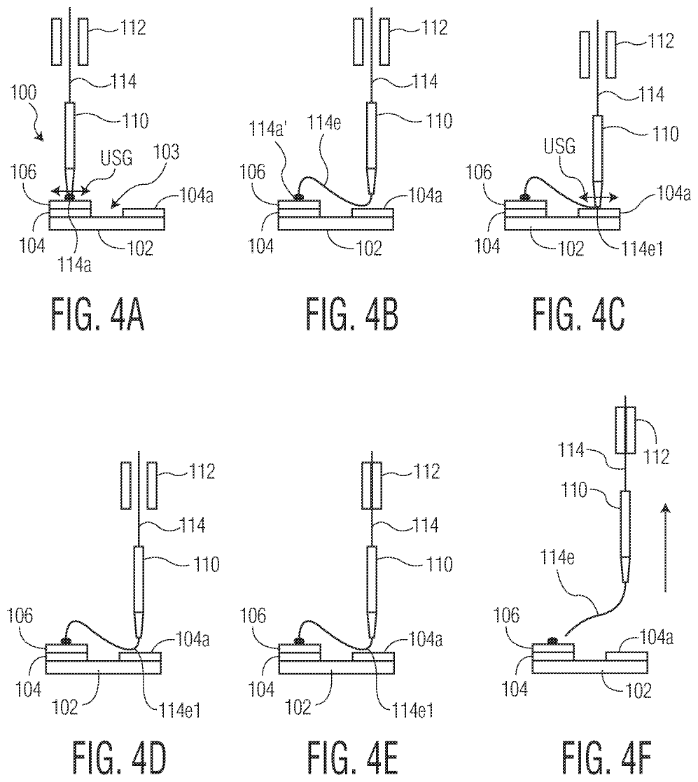

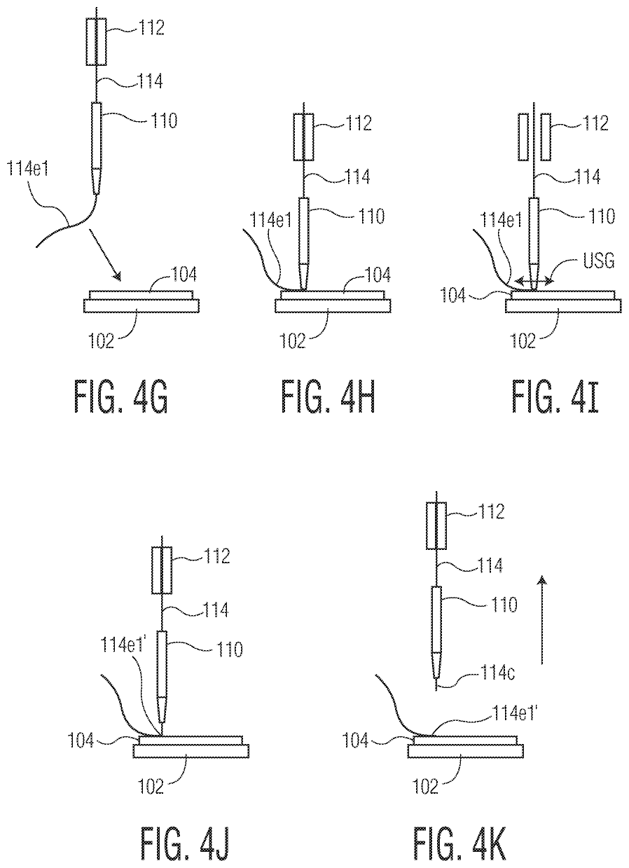

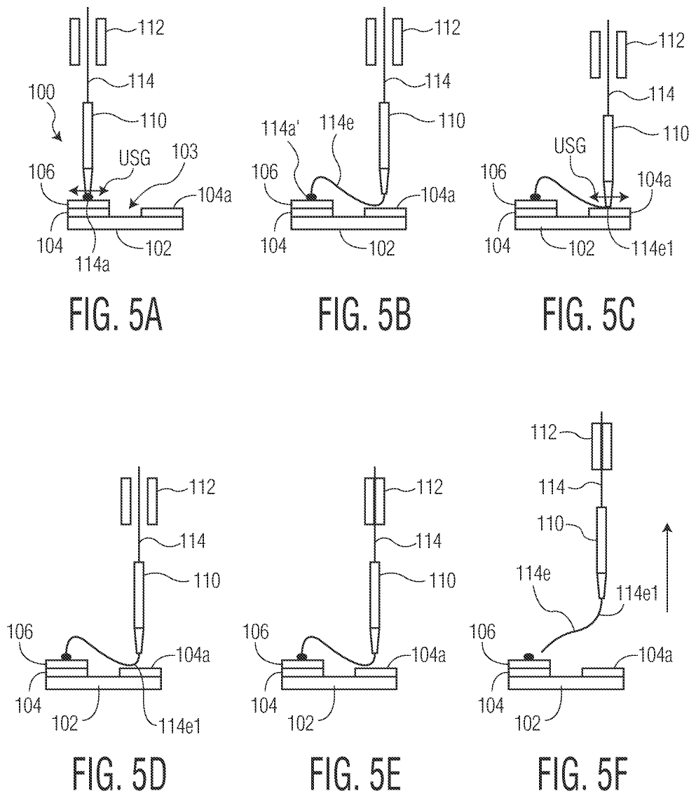

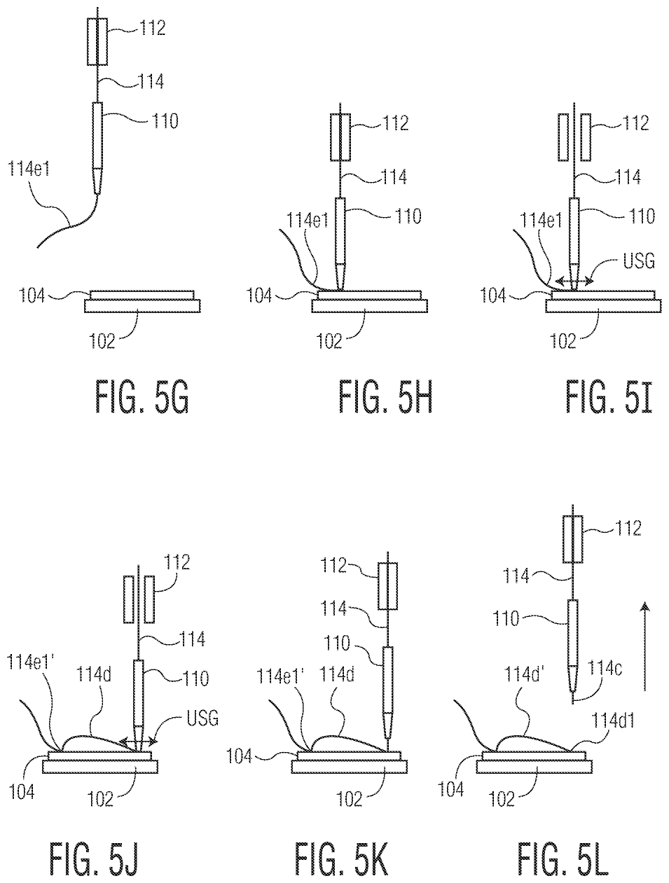

Further exemplary aspects of the invention relate to NSOL auto recovery processes, whereby advanced auto bond off processes may be utilized to provide a desirable wire tail, so that bonding processes may continue in an efficient manner. For example, see the processes illustrated in FIGS. 4A-4K and FIGS. 5A-5L.

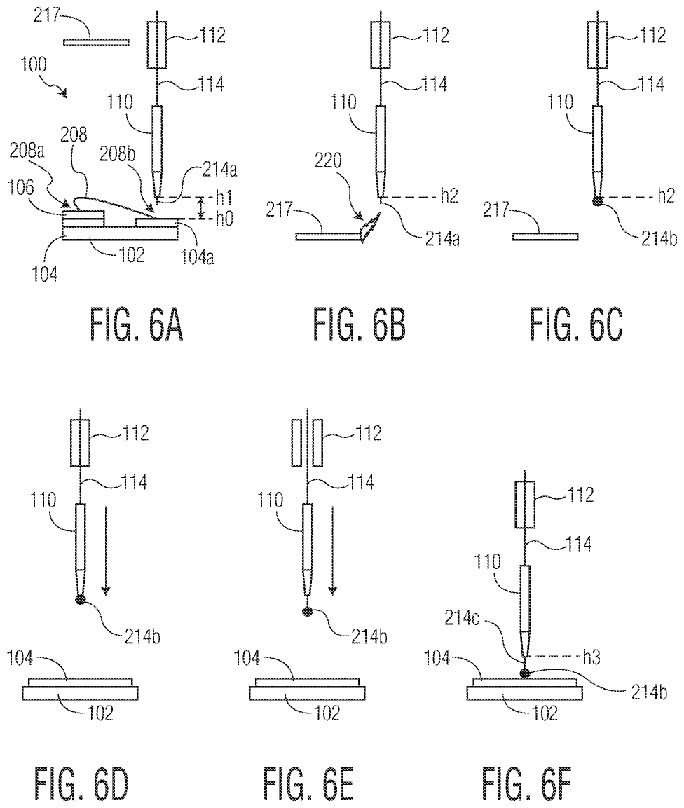

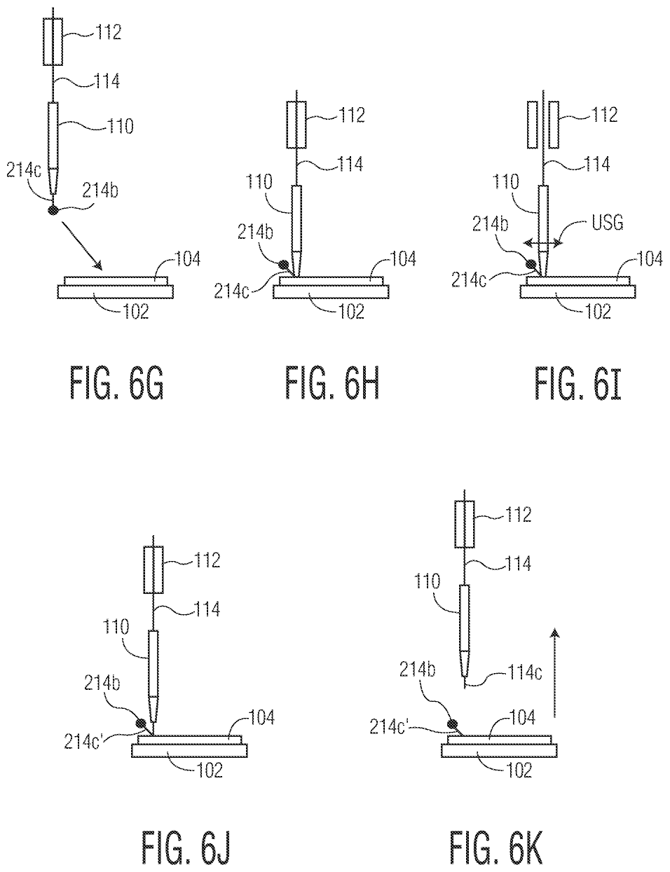

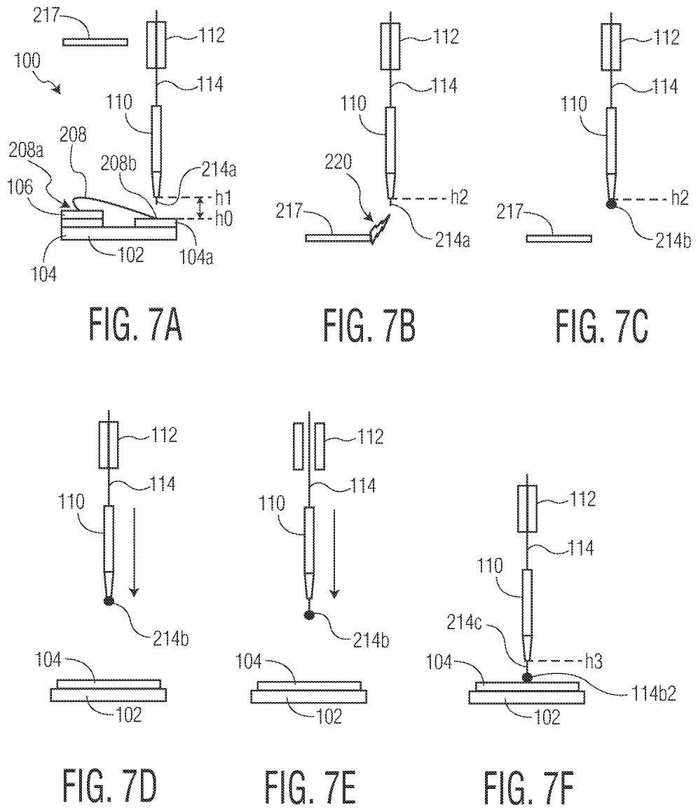

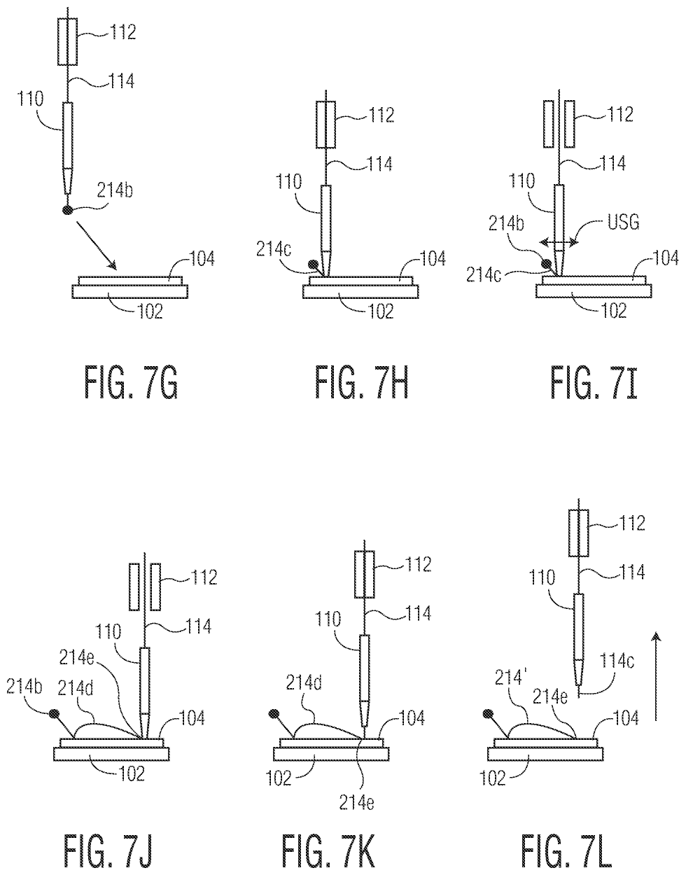

Further exemplary aspects of the invention relate to automatic short tail recovery processes, whereby an EFO (i.e., electronic flame off) assist may be utilized, which may be followed by an advanced automatic bond off process. For example, see the processes illustrated in FIGS. 6A-6K and FIGS. 7A-7L.

Certain of the advanced automatic bond off processes disclosed herein include one or more of: (i) pre-teaching of a bond off location, (ii) XYZ motions (i.e., angled or step motions) prior to contact for bending a wire tail or other wire portion, (iii) completing a bond off process, and/or (iv) completing a security wire loop/stitch to provide a desirable wire tail for subsequent wire bonding operations.

Certain of the processes disclosed herein include a “bond off” process, which may also be referred to as a re-bond process or a re-work process. Such processes may include (i) bonding the wire portion (e.g., a free air ball, a stitch bond portion, a wire tail, etc.) to a different bonding location. If a different bonding location is used, the different bonding location may be a different part of the original workpiece, or a different workpiece altogether.

Like reference numbers used in the present specification (including drawings) are intended to refer to like elements unless indicated otherwise.

As will be appreciated by those skilled in the art, the term “wire portion” is intended to be broadly construed, and not limited to any exact length. For example, each of FIGS. 4H and 5H illustrate bending of a wire portion 114e1 of a wire 114 (sometimes referred to herein as wire supply 114). In each case, attempts were made to bond this wire portion 114e1 to an original bonding location (see FIGS. 4C and 5C); however, wire portion 114e1 was not properly bonded to the original bonding location. Thus, wire portion 114e1 is bent at FIGS. 4H and 5H prior to a bond off process. It will be appreciated by those skilled in the art that the wire portion 114e1 “bonded” in FIGS. 4C and 5C may not have the exact same length as the wire portion 114e1 “bent” in FIGS. 4H and 5H.

As used herein, the terms “first”, “second”, “third”, “fourth”, etc. are used to refer to bonding locations and wire bonds. However, these terms are not intended to explicitly refer to any specific wire bond, specific wire bonding location, specific order (sequence) of wire bonding, etc. For example, a second bonding location may not exactly refer to a second of two bonding locations. As is understood by those skilled in the art, a wire loop may include more than two bonding locations, and more than two bonded portions.

Throughout the application, various bonding processes are described in connection with ultrasonic energy and/or illustrated with a “USG” reference; however, it is understood that bonding may or may not include ultrasonic energy. For example, certain wire bonds may be formed using bond force, heat and/or table scrub without ultrasonic energy.

Referring now to the drawings, FIG. 1A illustrates various elements of a wire bonding machine 100 including a support structure 102, a wire bonding tool 110 (e.g., a capillary), and a wire clamp 112. An exemplary workpiece 103 is supported by support structure 102. The workpiece 103 shown in FIG. 1A includes a semiconductor element 106 (e.g., a semiconductor die) bonded to a substrate 104 (e.g., a leadframe). According to a wire bonding program, wire bonding tool 110 is configured to use wire 114 to create a wire loop providing electrical interconnection between (i) a bonding location of semiconductor element 106 (e.g., a bond pad of semiconductor element 106) and (ii) a bonding location 104a of substrate 104 (e.g., a lead of a leadframe).

In FIG. 1A, a free air ball 114a has been formed on the end of wire 114, and ultrasonic energy (see “USG” reference) is being applied in an attempt to bond free air ball 114a to the bonding location of semiconductor element 106. However, as shown in FIG. 1B, free air ball 114a was not properly bonded to the bonding location. For example, such a condition may be referred to as “no stick on pad” (i.e., NSOP). Wire bonding machines often include detection systems for detecting if a portion of wire is properly bonded to a bonding location. For example, wire bonding machines marketed by Kulicke and Soffa Industries, Inc. often utilize a “BITS” process (i.e., bond integrity test system) to confirm that proper wire bonds have been (or have not been) formed. International Patent Application Publication WO 2009/002345, which is incorporated by reference herein in its entirety, illustrates exemplary details of such processes and related systems.

After it is detected that free air ball 114a was not properly bonded to the bonding location, wire bonding tool 110 moves toward another bonding location (see FIGS. 1C-1D). In the example shown in FIG. 1D, the bonding location utilized is the original second bonding location 104a of substrate 104. However, other bonding locations are contemplated. At FIG. 1D, free air ball 114a is bonded (e.g., ultrasonically bonded, see “USG” reference) to a bonding location of substrate 104 (e.g., to lead 104a). At FIG. 1E, wire bonding tool 110 is raised, with wire 114 (engaged with wire bonding tool 110) continuous with the bonded free air ball 114a′, to a position above the bonded free air ball 114a′ (e.g., to a tail height position). At FIG. 1F, a neck portion 114b of wire 114 above the bonded free air ball 114a′ is weakened. For example, neck portion 114b may be weakened by: (i) operating an ultrasonic transducer carrying wire bonding tool 110 to weaken neck portion 114b; and/or (ii) operating an xy table of wire bonding machine 100 carrying wire bonding tool 110 to weaken neck portion 114b. At FIG. 1G, the bonded free air ball 114a′ is separated from wire 114 such that a wire tail 114c extends below a tip of wire bonding tool 110. This wire tail may be used to continue a wire bonding process.

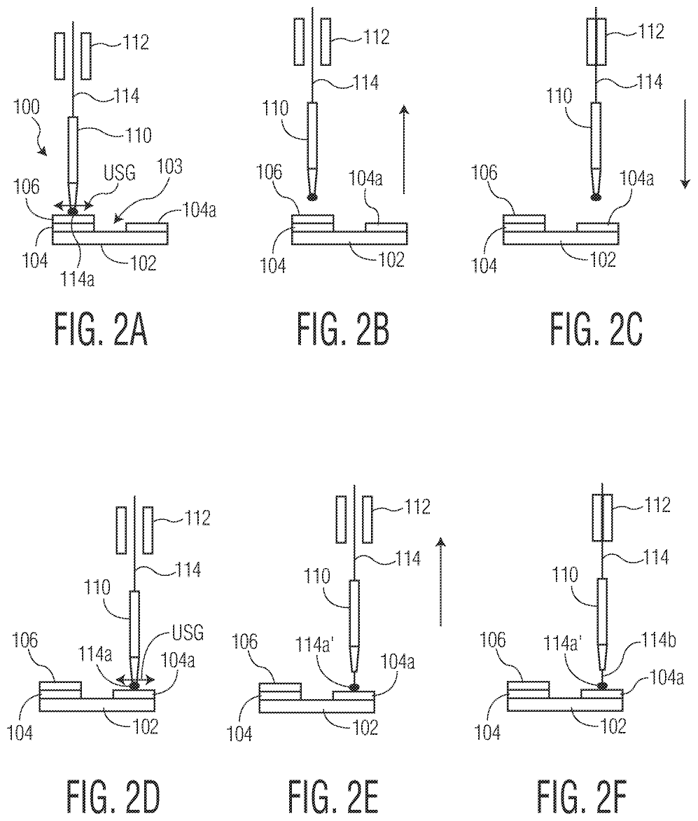

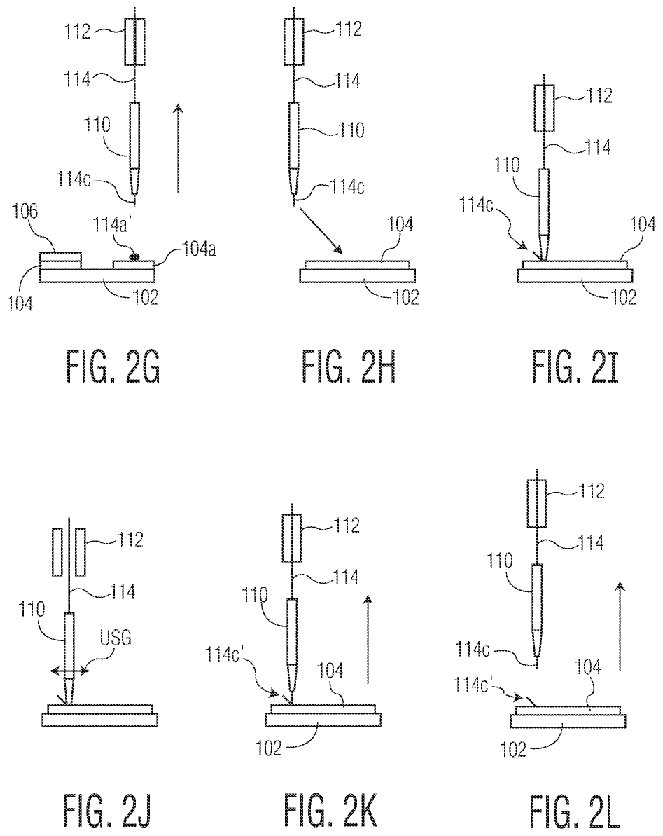

FIGS. 2A-2L illustrate another method of addressing a free air ball that is not properly bonded (e.g., an NSOP condition). FIGS. 2A-2G illustrate an identical sequence of operations as FIGS. 1A-1G. After the new wire tail 114c extends below a tip of wire bonding tool 110, wire bonding tool 110 is moved toward a substrate 104 (see FIG. 2H, where substrate may be the same substrate from FIGS. 2A-2G or a different substrate). For example, wire bonding tool 110 may approach a bonding location of substrate 104 at an angle to enable bending of the wire tail at FIG. 2I. For example, the approach at the angle is performed through xyz motions using a motion system of a bond head assembly (not shown) carrying wire bonding tool 110.

At FIG. 2I, wire tail 114c is bent against a bonding location of substrate 104 (with wire clamp 112 closed), and at FIG. 2J wire tail 114c is bonded to the bonding location of substrate 104 (with wire clamp 112 open). While FIGS. 2I-2J illustrate bending the wire tail 114c (FIG. 2I) against the same location to which the wire tail 114c is bonded (FIG. 2J), the invention is not limited thereto. For example, wire tail 114c may be bent against a bending location (e.g., a cup or other bending location, not shown) which is different from the bonding location (FIG. 2J).

At FIG. 2K, wire bonding tool 110 is raised, with wire 114 (engaged with wire bonding tool 110) continuous with the bonded wire tail 114c′, to a position above bonded wire tail 114c′ (e.g., to a tail height position). At FIG. 2L, bonded wire tail 114c′ is separated from wire 114 such that another wire tail 114c extends below a tip of wire bonding tool 110. This wire tail 114c may be used to continue a wire bonding process.

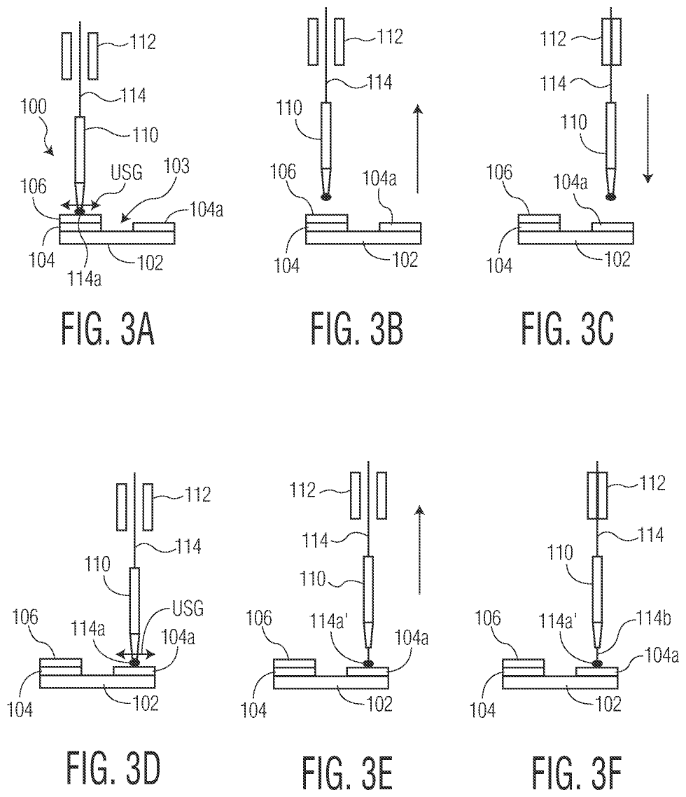

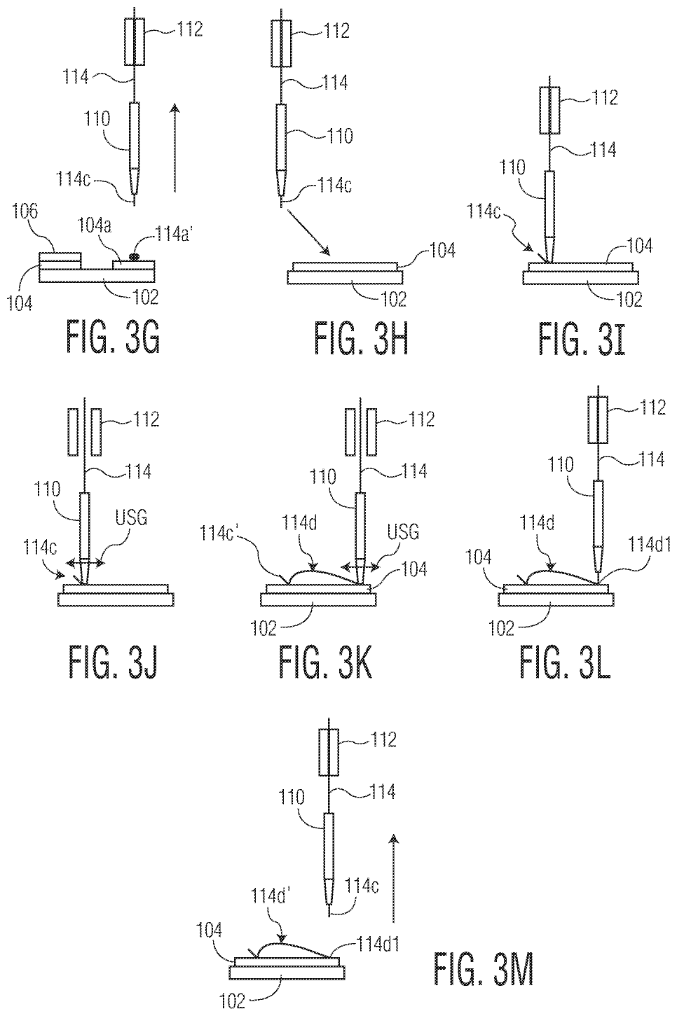

FIGS. 3A-3M illustrate another method of addressing a free air ball that is not properly bonded (e.g., an NSOP condition). FIGS. 3A-3J illustrate an identical sequence of operations as FIGS. 2A-2J. After wire tail 114c is bonded to the bonding location at FIG. 3J (e.g., to form a first bond of a wire loop), a length of wire 114d continuous with bonded wire tail 114c′ is extended to another bonding location (see FIG. 3K), and a portion of the length of wire is bonded to this bonding location to form a second bond of the wire loop (see. FIG. 3K). Wire bonding tool 110 is raised above the second bond (labelled as 114d1 in FIG. 3L) (e.g., to a tail height position) with a wire supply 114 still continuous with the second bond (see FIG. 3L). At FIG. 3M, the wire supply 114 is separated from the second bond 114d1 to form another wire tail 114c below the wire bonding tool 110 (and wire loop is now labelled as 114d′). This wire tail 114c may be used to continue a wire bonding process.

Each of FIGS. 1A-1G, FIGS. 2A-2L, and FIGS. 3A-3M relate to methods of operating wire bonding machines when a free air ball is not properly bonded to a bonding location (e.g., an NSOP, no stick on pad, situation). However, aspects of the invention relate to methods of operating wire bonding machines when other types of challenges arise (e.g., an NSOL, no stick on lead, situation; a short tail situation, etc.).

Referring now to FIGS. 4A-4K, a method of addressing a wire portion that is not properly bonded (e.g., an NSOL condition) is illustrated. In FIG. 4A, a free air ball 114a has been formed on the end of wire 114, and ultrasonic energy (USG) is being applied to bond free air ball 114a to a bonding location of semiconductor element 106 (e.g., to a bond pad of semiconductor element 106 of workpiece 103) using bonding tool 110 (e.g., wherein the bonding location may be considered a first bonding location). At FIG. 4B (with the free air ball now labelled as bonded free air ball 114a′), a length of wire 114e, continuous with the first bond (i.e., bonded free air ball 114a′), is being extended to a second bonding location (e.g., lead 104a of leadframe 104). At FIG. 4C, ultrasonic energy (see “USG” reference) is being applied in an attempt to bond a wire portion 114e1 of wire length 114e (e.g., an end portion 114e1 of wire length) to the second bonding location. However, as shown in FIG. 4D, wire portion 114e1 was not properly bonded to the second bonding location. For example, such a condition may be referred to as “no stick on lead” (i.e., NSOL). As described above, wire bonding machines often include detection systems for detecting if a portion of wire is properly bonded to a bonding location. For example, wire bonding machines marketed by Kulicke and Soffa Industries, Inc. often utilize a “BITS” process (i.e., bond integrity test system) to confirm that proper wire bonds have been formed. International Patent Application Publication WO 2009/002345, which is incorporated by reference herein in its entirety, illustrates exemplary details of such processes and related systems.

At FIG. 4E, with wire clamp 112 closed, it is detected that wire portion 114e1 was not properly bonded to the second bonding location, and length of wire 114e (including wire portion 114e1) is separated from the first bond (bonded free air ball 114a′) at FIG. 4F. At FIG. 4G, wire bonding tool 110 is moved toward a bonding location of substrate 104. For example, wire bonding tool 110 may approach the bonding location of substrate 104 at an angle to enable bending wire portion 114e1 at FIG. 4H. For example, the approach at the angle is performed through xyz motions using a motion system of a bond head assembly (not shown) carrying wire bonding tool 110.

At FIG. 4H, wire portion 114e1 (as part of length of wire 114e) is bent against a bonding location of substrate 104 (with wire clamp 112 closed). At FIG. 4I wire portion 114e1 is bonded to the bonding location of substrate 104 (with wire clamp 112 open). While FIGS. 4H-4I illustrate bending the wire portion 114e1 (FIG. 4H) against the same location to which the wire portion 114e1 is bonded (FIG. 4I), the invention is not limited thereto. For example, wire portion 114e1 may be bent against a bending location (e.g., a cup or other bending location, not shown) which is different from the bonding location (FIG. 4I). Prior to FIG. 4J, wire bonding tool 110 has been raised (with the wire clamp open) to a position above bonded wire portion 114e1′ (e.g., to a tail height position). Then at FIG. 4J, wire clamp 112 is closed, with wire 114 (engaged with wire bonding tool 110) continuous with the bonded wire portion (now labelled as 114e1′). At FIG. 4K, bonded wire portion 114e1′ is separated from wire 114 such that another wire tail 114c extends below a tip of wire bonding tool 110. This wire tail 114c may be used to continue a wire bonding process.

FIGS. 5A-5L illustrate another method of addressing a wire portion that is not properly bonded (e.g., an NSOL condition). FIGS. 5A-5I illustrate an identical sequence of operations as FIGS. 4A-4I. After wire portion 114e1 is bonded to the bonding location (e.g., a third bonding location) at FIG. 5I (e.g., to form a first bond of a wire loop labelled as 114e1′ in FIG. 5J), a length of wire 114d continuous with bonded wire portion 114e1′ is extended to another bonding location (e.g., a fourth bonding location) (see FIG. 5J), and a portion of the length of wire is bonded to this bonding location to form a second bond of the wire loop (see. FIG. 5J). Wire bonding tool 110 is raised above the second bond (labelled as 114d1 in FIG. 5L) (e.g., to a tail height position) with a wire supply 114 still continuous with the second bond (see FIG. 5K). At FIG. 5L, the wire supply 114 is separated from the second bond 114d1 to form another wire tail 114c below the wire bonding tool 110 (and wire loop is now labelled as 114d′). This wire tail 114c may be used to continue a wire bonding process.

Referring now to FIGS. 6A-6K, a method of addressing a short tail condition on a wire bonding machine 100 is illustrated. In FIG. 6A, after formation of wire loop 208 (including a length of wire between first bond 208a and second bond 208b), wire bonding tool 110 has been raised to height h1 (referred to as “tail height”) above height h0. In a normal operation, a detection system can detect the presence of a wire tail still connected to (continuous with) second bond 208b. However, in the example shown in FIG. 6A, a short tail condition exists. That is, the wire tail 214a extending from the tip of wire bonding tool 110 in FIG. 6A is short, and is not connected to second bond 208b.

As provided above, wire bonding machines marketed by Kulicke and Soffa Industries, Inc. often utilize a “BITS” process (i.e., bond integrity test system) to confirm that proper wire bonds have been formed. International Patent Application Publication WO 2009/002345, which is incorporated by reference herein in its entirety, illustrates exemplary details of such processes and related systems. Such a BITS process may be used to detect the short tail condition; however, it is understood that other techniques may be used for detecting the short tail condition.

At FIGS. 6B-6C, a free air ball 214b is formed using short wire tail 214a. For example, an electronic flame-off device 217 is used to melt short wire tail 214a to form free air ball 214b (e.g., at a height h2, which may be different and/or higher than h1). As will be appreciated by those skilled in the art, free air ball 214b is likely smaller than a typical free air ball for the specific wire bonding application.

FIGS. 6D-6F illustrate an exemplary process for forming a first wire tail 214c. More specifically: at FIG. 6D (with wire clamp 112 closed), wire bonding tool 110 is lowered (e.g., by lowering a bond head assembly carrying wire bonding tool 110, not shown) toward substrate 104 (which may be part of substrate 104 from FIG. 6A, or a different substrate); at FIG. 6E (with wire clamp 112 open), wire bonding tool 110 is lowered further toward substrate 104; and at FIG. 6F (with wire clamp 112 closed), contact has been detected between free air ball 214b and substrate 104. Thus, through this process (or a different process), a length of wire has been extended below a tip of the wire bonding tool, continuous with the free air ball, to create a first wire tail 214c (e.g., at a height h3). U.S. Pat. No. 9,165,842 describes methods for creating such a wire tail after detecting a short tail. Such exemplary methods may also be used, within the scope of the invention, in connection with extending a length of wire below a tip of the wire bonding tool to create a first wire tail.

At FIG. 6G, wire bonding tool 110 is moved toward a bonding location of substrate 104. For example, wire bonding tool 110 may approach the bonding location of substrate 104 at an angle to enable bending of wire tail 214c at FIG. 6H. For example, the approach at the angle is performed through xyz motions using a motion system of a bond head assembly (not shown) carrying wire bonding tool 110.

At FIG. 6H, wire tail 214c is bent against a bonding location of substrate 104 (with wire clamp 112 closed). At FIG. 6I, wire tail 214c is bonded to the bonding location of substrate 104 (with wire clamp 112 open). While FIGS. 6H-6I illustrate bending the wire tail 214c (FIG. 6H) against the same location to which the wire tail 214c is bonded (FIG. 6I), the invention is not limited thereto. For example, wire tail 214c may be bent against a bending location (e.g., a cup or other bending location, not shown) which is different from the bonding location (FIG. 6I). Prior to FIG. 6J, wire bonding tool 110 has been raised (with the wire clamp open) to a position above bonded wire tail 214c′ (e.g., to a tail height position). Then at FIG. 6J, wire clamp 112 is closed, with wire 114 (engaged with wire bonding tool 110) continuous with the bonded wire tail 214c′. At FIG. 6K, bonded wire tail 214c′ is separated from wire 114 such that another wire tail 114c extends below a tip of wire bonding tool 110. This wire tail 114c may be used to continue a wire bonding process.

FIGS. 7A-7L illustrate another method of addressing a short tail condition on a wire bonding machine. FIGS. 7A-7I illustrate an identical sequence of operations as FIGS. 6A-6I. After wire tail 214c is bonded to the bonding location of substrate 104 (FIG. 7I) (e.g., to form a first bond of a wire loop labelled as 214c′), a length of wire 214d continuous with bonded wire tail 214c′ is extended to another bonding location (e.g., a second bonding location) (see FIG. 7J), and a portion of the length of wire is bonded to this bonding location to form a second bond 214e of the wire loop (see. FIG. 7J). Wire bonding tool 110 is raised above second bond 214e (e.g., to a tail height position) with a wire supply 114 still continuous with the second bond (see FIG. 7K). At FIG. 7L, the wire supply 114 is separated from the second bond 214e to form another wire tail 114c below the wire bonding tool 110 (and wire loop is now labelled as 214′). This wire tail 114c may be used to continue a wire bonding process.

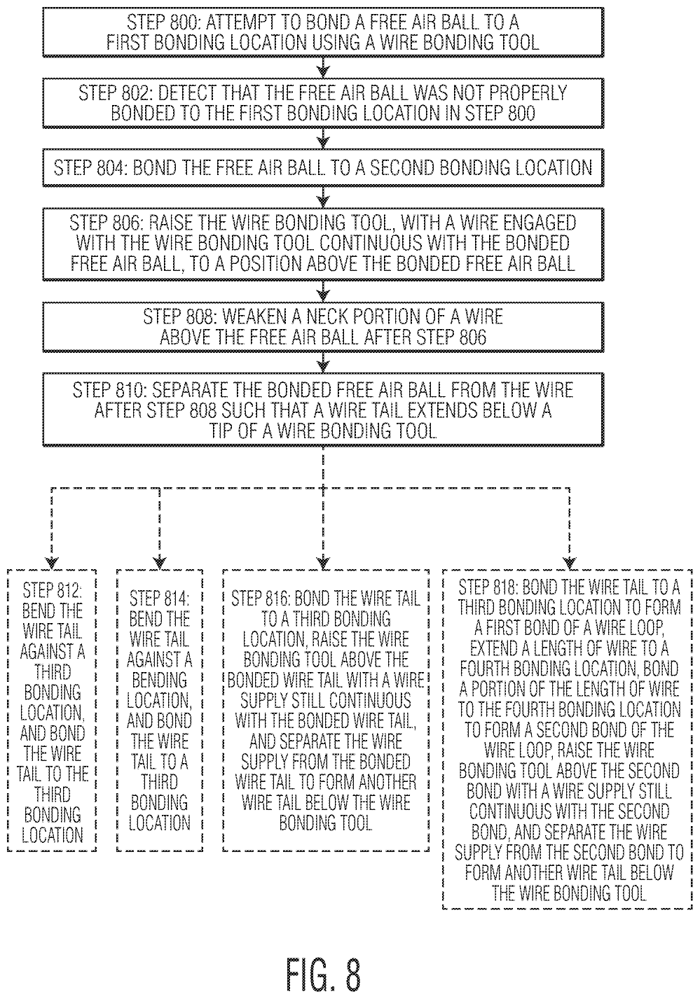

FIGS. 8-10 are flow diagrams illustrating various methods of operating a wire bonding machine. As is understood by those skilled in the art, certain steps included in the flow diagrams may be omitted; certain additional steps may be added; and the order of the steps may be altered from the order illustrated—all within the scope of the invention.

Referring now to FIG. 8, at Step 800, an attempt is made to bond a free air ball to a first bonding location using a wire bonding tool (e.g., see FIG. 1A, FIG. 2A, FIG. 3A). At Step 802, it is detected that the free air ball was not properly bonded to the first bonding location in Step 800 (e.g., see unbonded free air ball in FIG. 1B, FIG. 2B, FIG. 3B). At Step 804, the free air ball is bonded to a second bonding location (e.g., see FIG. 1D, FIG. 2D, FIG. 3D). At Step 806, the wire bonding tool is raised, with a wire engaged with the wire bonding tool continuous with the bonded free air ball, to a position above the bonded free air ball (e.g., see FIG. 1E, FIG. 2E, FIG. 3E). At Step 808, a neck portion of a wire is weakened above the free air ball after Step 806. At Step 810, the bonded free air ball is separated from the wire after Step 808 such that a wire tail extends below a tip of a wire bonding tool (e.g., see FIG. 1G, FIG. 2G, FIG. 3G).

In certain embodiments, at optional Step 812, the wire tail is bent against a third bonding location (e.g., see FIG. 2I, FIG. 31), and the wire tail is bonded to the third bonding location (e.g., see FIG. 2J, FIG. 3J). In certain embodiments, at optional Step 814, the wire tail is bent against a bending location, and the wire tail is bonded to a third bonding location. In certain embodiments, at optional Step 816, the wire tail is bonded to a third bonding location (e.g., see FIG. 2J); the wire bonding tool is raised above the bonded wire tail with a wire supply still continuous with the bonded wire tail (e.g., see FIG. 2K); and the wire supply is separated from the bonded wire tail to form another wire tail below the wire bonding tool (e.g., see FIG. 2L). In certain embodiments, at optional Step 818, the wire tail is bonded to a third bonding location to form a first bond of a wire loop (e.g., see FIG. 3J); a length of wire is extended to a fourth bonding location (e.g., see FIG. 3K); a portion of the length of wire is bonded to the fourth bonding location to form a second bond of the wire loop (e.g., see FIG. 3K); the wire bonding tool is raised above the second bond with a wire supply still continuous with the second bond (e.g., see FIG. 3L); and the wire supply is separated from the second bond to form another wire tail below the wire bonding tool (e.g., see FIG. 3M).

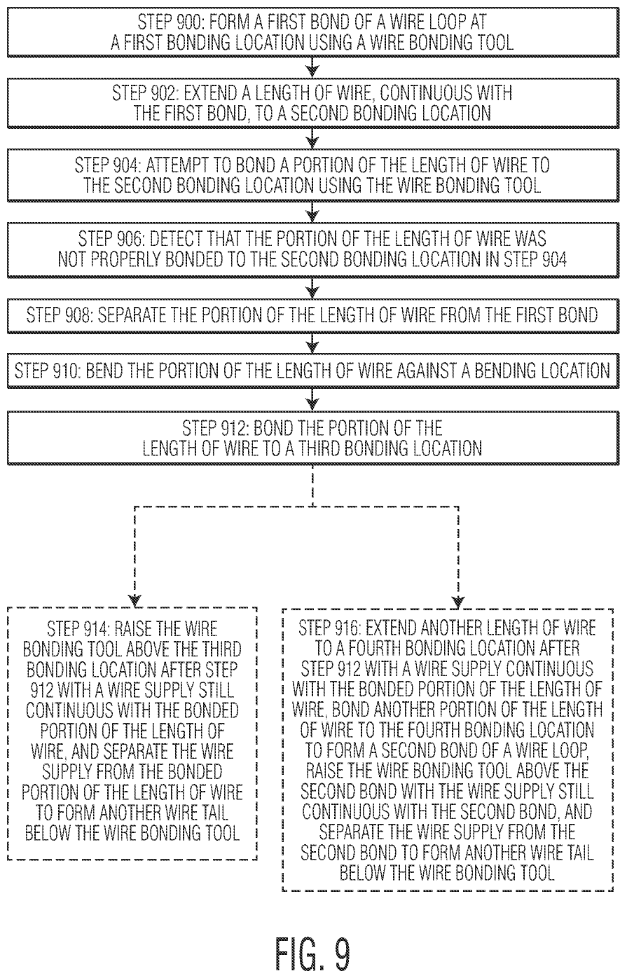

Referring now to FIG. 9, at Step 900, a first bond of a wire loop is formed at a first bonding location using a wire bonding tool (e.g., see FIG. 4A, FIG. 5A). At Step 902, a length of wire is extended, continuous with the first bond, to a second bonding location (e.g., see FIG. 4B, FIG. 5B). At Step 904, a portion of the length of wire is attempted to bond to the second bonding location using the wire bonding tool (e.g., see FIG. 4C, FIG. 5C). At Step 906, it is detected that the portion of the length of wire was not properly bonded to the second bonding location in Step 904 (e.g., see unbonded length of wire in FIG. 4D, FIG. 5D). At Step 908, the portion of the length of wire is separated from the first bond (e.g., see FIG. 4F, FIG. 5F). At Step 910, the portion of the length of wire is bent against a bending location (e.g., see FIG. 4H, FIG. 5H). At Step 912, the portion of the length of wire is bonded to a third bonding location (e.g., see FIG. 4I, FIG. 5I).

In certain embodiments, at optional Step 914, the wire bonding tool is raised above the third bonding location after Step 912 with a wire supply still continuous with the bonded portion of the length of wire, and the wire supply is separated from the bonded portion of the length of wire to form another wire tail below the wire bonding tool (e.g., see FIGS. 4J and 4K). In certain embodiments, at optional Step 916, another length of wire is extended to a fourth bonding location after Step 912 with a wire supply continuous with the bonded portion of the length of wire (e.g., see FIG. 5J); another portion of the length of wire is bonded to the fourth bonding location to form a second bond of a wire loop (e.g., see FIG. 5J); the wire bonding tool is raised above the second bond with the wire supply still continuous with the second bond (e.g., see FIG. 5K); and the wire supply is separated from the second bond to form another wire tail below the wire bonding tool (e.g., see FIG. 5L).

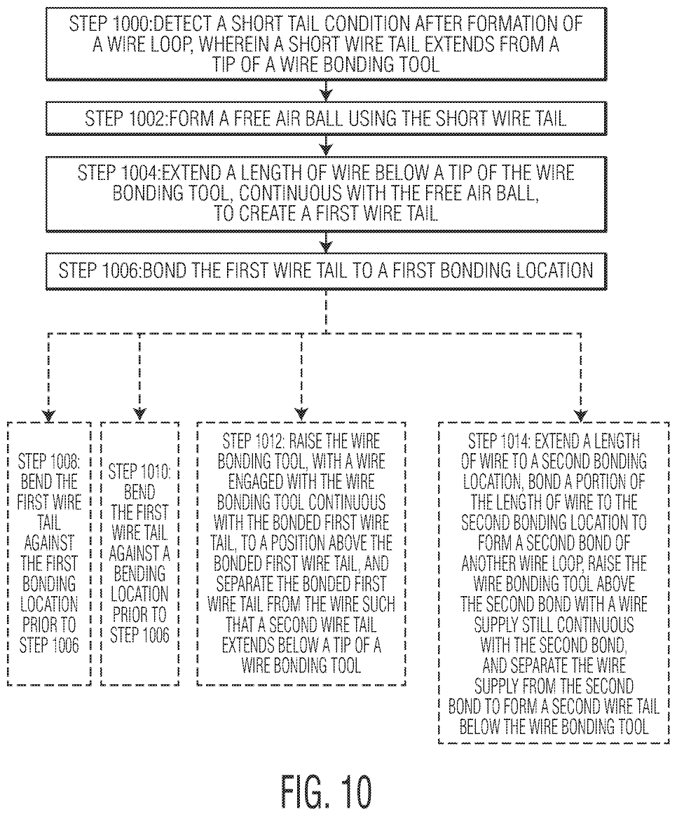

Referring now to FIG. 10, at Step 1000, a short tail condition is detected after formation of a wire loop, wherein a short wire tail extends from a tip of a wire bonding tool (e.g., see short tail condition in FIG. 6A, FIG. 7A). At Step 1002, a free air ball is formed using the short wire tail (e.g., see FIGS. 6B-6C, FIGS. 7B-7C). At Step 1004, a length of wire is extended below a tip of the wire bonding tool, continuous with the free air ball, to create a first wire tail (e.g., see FIGS. 6D-6F, FIGS. 7D-7F). At Step 1006, the first wire tail is bonded to a first bonding location (e.g., see FIG. 6I, FIG. 7I).

In certain embodiments, at optional Step 1008, the first wire tail is bent against the first bonding location prior to Step 1006 (e.g., see FIG. 6H, FIG. 7H). In certain embodiments, at optional Step 1010, the first wire tail is bent against a bending location prior to Step 1006. In certain embodiments, at optional Step 1012, the wire bonding tool, with a wire engaged with the wire bonding tool continuous with the bonded first wire tail, is raised to a position above the bonded first wire tail (e.g., see FIG. 6J); and the bonded first wire tail is separated from the wire such that a second wire tail extends below a tip of a wire bonding tool (e.g., see FIG. 6K). In certain embodiments, at optional Step 1014, a length of wire is extended to a second bonding location; a portion of the length of wire is bonded to the second bonding location to form a second bond of another wire loop (e.g., see FIG. 7J); the wire bonding tool is raised above the second bond with a wire supply still continuous with the second bond (e.g., see FIG. 7K); and the wire supply is separated from the second bond to form a second wire tail below the wire bonding tool (e.g., see FIG. 7L).

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method of operating a wire bonding machine, the method comprising the steps of:
(a) attempting to bond a free air ball to a first bonding location using a wire bonding tool;
(b) detecting that the free air ball was not properly bonded to the first bonding location in step (a);
(c) bonding the free air ball to a second bonding location;
(d) raising the wire bonding tool, with a wire engaged with the wire bonding tool continuous with the bonded free air ball, to a position above the bonded free air ball;
(e) weakening a neck portion of a wire above the free air ball after step (d); and
(f) separating the bonded free air ball from the wire after step (e) such that a wire tail extends below a tip of a wire bonding tool.

2. The method of claim 1 further comprising the step of (g1) bending the wire tail against a third bonding location, and (g2) bonding the wire tail to the third bonding location.

3. The method of claim 2 wherein, prior to step (g1), the method includes approaching the third bonding location at an angle to enable the bending at step (g1).

4. The method of claim 3 wherein prior to step (g1), the method includes approaching the third bonding location at the angle by performing xyz motions using a motion system of a bond head assembly carrying the wire bonding tool.

5. The method of claim 2 wherein a wire clamp above the wire bonding tool is closed during step (g1), and open during step (g2).

6. The method of claim 1 further comprising the step of (g1) bending the wire tail against a bending location, and (g2) bonding the wire tail to a third bonding location.

7. The method of claim 6 wherein a wire clamp above the wire bonding tool is closed during steps (91), and open during step (g2).

8. The method of claim 1 further comprising the steps of bonding the wire tail to a third bonding location, raising the wire bonding tool above the bonded wire tail with a wire supply still continuous with the bonded wire tail, and separating the wire supply from the bonded wire tail to form another wire tail below the wire bonding tool.

9. The method of claim 1 further comprising the steps of bonding the wire tail to a third bonding location to form a first bond of a wire loop, extending a length of wire to a fourth bonding location, bonding a portion of the length of wire to the fourth bonding location to form a second bond of the wire loop, raising the wire bonding tool above the second bond with a wire supply still continuous with the second bond, and separating the wire supply from the second bond to form another wire tail below the wire bonding tool.

10. The method of claim 1 wherein step (e) includes weakening the neck portion of the wire by at least one of (i) operating an ultrasonic transducer carrying the wire bonding tool to weaken the neck portion, and (ii) operating an xy table of the wire bonding machine carrying the wire bonding tool to weaken the neck portion.

11. A method of operating a wire bonding machine, the method comprising the steps of:
(a) forming a first bond of a wire loop at a first bonding location using a wire bonding tool;
(b) extending a length of wire, continuous with the first bond, to a second bonding location;
(c) attempting to bond a portion of the length of wire to the second bonding location using the wire bonding tool;
(d) detecting that the portion of the length of wire was not properly bonded to the second bonding location in step (c);
(e) separating the portion of the length of wire from the first bond;
(f) bending the portion of the length of wire against a bending location; and
(g) bonding the portion of the length of wire to a third bonding location.

12. The method of claim 11 wherein the bending location is the third bonding location.

13. The method of claim 11 wherein the bending location is different from the third bonding location.

14. The method of claim 11 wherein, prior to step (f), the method includes approaching the third bonding location at an angle to enable the bending at step (f).

15. The method of claim 14 wherein prior to step (f), the method includes approaching the third bonding location at the angle by performing xyz motions using a motion system of a bond head assembly carrying the wire bonding tool.

16. The method of claim 11 wherein a wire clamp above the wire bonding tool is closed during step (f), and open during step (g).

17. The method of claim 11 further comprising the steps of (h) raising the wire bonding tool above the third bonding location after step (g) with a wire supply still continuous with the bonded portion of the length of wire, and (h) separating the wire supply from the bonded portion of the length of wire to form another wire tail below the wire bonding tool.

18. The method of claim 11 further comprising the steps of (h) extending another length of wire to a fourth bonding location after step (g) with a wire supply continuous with the bonded portion of the length of wire, (i) bonding another portion of the length of wire to the fourth bonding location to form a second bond of a wire loop, (j) raising the wire bonding tool above the second bond with the wire supply still continuous with the second bond, and (k) separating the wire supply from the second bond to form another wire tail below the wire bonding tool.

19. A method of operating a wire bonding machine, the method comprising the steps of:
(a) detecting a short tail condition after formation of a wire loop, wherein a short wire tail extends from a tip of a wire bonding tool;
(b) forming a free air ball using the short wire tail;
(c) extending a length of wire below a tip of the wire bonding tool, continuous with the free air ball, to create a first wire tail; and
(d) bonding the first wire tail to a first bonding location.

20. The method of claim 19 further comprising the step of bending the first wire tail against the first bonding location prior to step (d).

21. The method of claim 20 wherein, prior to the step of bending, the method includes approaching the first bonding location at an angle to enable the bending.

22. The method of claim 20 wherein prior to the step of bending, the method includes approaching the first bonding location at an angle by performing xyz motions using a motion system of a bond head assembly carrying the wire bonding tool.

23. The method of claim 20 wherein a wire clamp above the wire bonding tool is closed during the step of bending, and open during step (d).

24. The method of claim 19 further comprising bending the first wire tail against a bending location prior to step (d).

25. The method of claim 24 wherein a wire clamp above the wire bonding tool is closed during the step of bending, and open during step (d).

26. The method of claim 19 further comprising the steps of (e) raising the wire bonding tool, with a wire engaged with the wire bonding tool continuous with the bonded first wire tail, to a position above the bonded first wire tail, and (f) separating the bonded first wire tail from the wire after step (e) such that a second wire tail extends below a tip of a wire bonding tool.

27. The method of claim 19 further comprising the steps of extending a length of wire to a second bonding location, bonding a portion of the length of wire to the second bonding location to form a second bond of another wire loop, raising the wire bonding tool above the second bond with a wire supply still continuous with the second bond, and separating the wire supply from the second bond to form a second wire tail below the wire bonding tool.
